(19) United States
(12) Patent Application Publication
(10) Pub. No.: US 2022/0297563 A1
(43) Pub. Date: Sep. 22, 2022

(54) Auxiliary Battery System for Vehicle

(71) Applicants: Hyundai Motor Company, Seoul (KR); Kia Corporation, Seoul (KR)

(72) Inventors: Jin Ho Jo, Gyeonggi-do (KR); Ki Seon Ryu, Seoul (KR)

(21) Appl. No.: 17/528,275

(22) Filed: Nov. 17, 2021

(30) Foreign Application Priority Data
Mar. 19, 2021 (KR) 10-2021-0035721

(51) Int. Cl. B60L 53/62; B60R 16/033; B60L 58/12; B60L 53/53; H02J 7/00

(52) U.S. Cl. CPC B60L 53/62; B60R 16/033; B60L 58/12; B60L 53/53; H02J 7/0048; H02J 7/00712; H02J 7/0071; H02J 7/00032

(57) ABSTRACT

An auxiliary battery system for a vehicle includes an auxiliary battery configured to provide power to an electronic device of the vehicle; a battery sensor configured to calculate a state of charge of the auxiliary battery; and a control unit configured to control charging of the auxiliary battery by the high voltage battery, in which a charging strategy of the auxiliary battery is different depending upon whether communication between the battery sensor and the control unit is activated by a request of the battery sensor or activated by a wake-up of the control unit.

### CROSS REFERENCE TO RELATED APPLICATION

The present application claims under 35 U.S.C. § 119(a) the benefit of Korean Patent Application No. 10-2021-0035721 filed on Mar. 19, 2021, the entire contents of which are incorporated by reference herein.

### BACKGROUND

### (a) Technical Field

The present disclosure relates to an auxiliary battery system for a vehicle, which may prevent a phenomenon in which power is unnecessarily consumed by a frequent charging request of an auxiliary battery, thereby solving a discharging problem of a high voltage battery or the auxiliary battery during long-term parking, and increasing durability of the auxiliary battery and the high voltage battery.

### (b) Description of the Related Art

An electric vehicle or a fuel cell vehicle each use a high voltage battery system of 300 V or more for driving. Further, the electric vehicle or the fuel cell vehicle simultaneously use an auxiliary battery of a 12 V system for using various electronic devices. When a controller in the vehicle is operated in a non-starting state (parking/ACC/IGN ON) where a generator (LDC) is not operated in the electric vehicle, an excessive power consumption of the auxiliary battery by the controller may occur in the vehicle. Further, the controller should perform many functions even in the non-starting state for a driver.

In this case, if the power of the auxiliary battery is carelessly used, it may cause a failure of the vehicle to start later due to discharging of the auxiliary battery. To prevent such a problem, there is also conventionally a logic charging the auxiliary battery.

Conventionally, to prevent the discharging of the auxiliary battery, the charging-related controller (LDC, BMS) for the vehicle is operated for charging the auxiliary battery when the controller satisfies a certain condition. However, such a function is available only during parking of the vehicle, and the controller checks a charging rate or state of charge (SOC) of the auxiliary battery only when 24 hours (period) elapses after parking. The controller performs and terminates charging only for a limited time (timer) without a target value only when the SOC is low at the check timing.

Alternatively, if the state of charge of the auxiliary battery is reduced to a certain SOC or less, the charging may also be immediately performed. However, in this case, since the SOC of the auxiliary battery is not always checked during parking, there occurs a situation in which the charging is not available due to lack of the SOC during parking.

Further, upon attempting to charge the auxiliary battery during parking even if the charging is performed, the communication of the vehicle does not enter into a sleep mode during parking by the re-request for charging repeated upon not reaching a charging target SOC, and non-sleep of the communication of the vehicle occurs. Therefore, there is a problem of causing unnecessary consumption of the electric energy stored in the vehicle and discharging of the auxiliary battery.

The foregoing explained as the background is intended merely to aid in the understanding of the background of the present disclosure, and is not intended to mean that the present disclosure falls within the purview of the related art that is already known to those skilled in the art.

### SUMMARY

The present disclosure provides an auxiliary battery system for a vehicle, which may prevent a phenomenon in which power of a high voltage battery is unnecessarily consumed by a frequent charging request of an auxiliary battery, thereby solving a discharging problem of the high voltage battery upon long-term parking and increasing durability of the auxiliary battery and the high voltage battery.

An auxiliary battery system for a vehicle according to the present disclosure for achieving the object includes an auxiliary battery charged by a high voltage battery for driving a vehicle, and configured to provide power to an electronic device of the vehicle; a battery sensor configured to calculate a state of charge of the auxiliary battery; and a control unit configured to perform communication with the battery sensor, and to control charging of the auxiliary battery by the high voltage battery, in which a charging strategy of the auxiliary battery may be different depending upon whether the communication between the battery sensor and the control unit is activated by a request of the battery sensor or activated by a wake-up of the control unit.

The auxiliary battery system for the vehicle may further include a memory configured to store a flag about whether the communication between the battery sensor and the control unit is activated by the request of the battery sensor or activated by the wake-up of the control unit.

The memory may be provided in the battery sensor.

The state of the flag may be divided into an OFF state and an ON state, and switched into the ON state if the communication between the battery sensor and the control unit is activated by the charging request of the battery sensor.

In the case where the flag is switched into the ON state by the charging request of the battery sensor, the flag may be switched into the OFF state if the communication between the battery sensor and the control unit is activated by the wake-up of the control unit.

The state of the flag may be divided into an OFF state and an ON state, and switched into the ON state if the communication between the battery sensor and the control unit is activated by the wake-up of the control unit and then there exists the charging request of the battery sensor.

In the case where the flag is switched into the ON state by the wake-up of the control unit and the charging request of the battery sensor, the flag may be switched into the OFF state if the communication between the battery sensor and the control unit is inactivated by the control unit entering a sleep mode.

The state of the flag may be divided into an OFF state and an ON state, and switched into the ON state if the communication between the battery sensor and the control unit is activated by the charging request of the battery sensor and if the communication between the battery sensor and the control unit is activated by the wake-up of the control unit and then there exists the charging request of the battery sensor.

In the case where the flag is in the OFF state, the auxiliary battery may be charged if the state of charge of the auxiliary battery is a first standard level or less.

In the case where the flag is in the ON state, the auxiliary battery may be charged if a discharging amount or a discharging rate of the auxiliary battery is a second standard level or more.

The auxiliary battery may be charged by the battery sensor making the charging request to the control unit.

The control unit may terminate the charging of the auxiliary battery if the state of charge of the auxiliary battery reaches a first standard level upon charging the auxiliary battery.

The control unit may terminate the charging of the auxiliary battery if a charging current is maintained to a fourth standard level or less upon charging the auxiliary battery.

The control unit may measure a charging time upon charging the auxiliary battery, and terminate the charging of the auxiliary battery if the charging time reaches a third standard level.

The control unit may terminate the charging if the communication between the battery sensor and the control unit is inactivated by the control unit entering a sleep mode upon charging the auxiliary battery.

The auxiliary battery system for the vehicle according to the present disclosure may prevent the phenomenon in which the power of the high voltage battery is unnecessarily consumed by the frequent charging request of the auxiliary battery, thereby solving the discharging problem of the high voltage battery during long-term parking and increasing the durability of the auxiliary battery and the high voltage battery.

### BRIEF DESCRIPTION OF THE DRAWINGS

The above and other objects, features and other advantages of the present disclosure will be more clearly understood from the following detailed description when taken in conjunction with the accompanying drawings, in which:

FIG. 1 is a diagram illustrating a configuration of an auxiliary battery system for a vehicle according to an exemplary embodiment of the present disclosure.

FIG. 2 is a diagram illustrating a configuration of a battery sensor of the auxiliary battery system for the vehicle according to the exemplary embodiment of the present disclosure.

FIG. 3 is a diagram illustrating a flag switching logic of the auxiliary battery system for the vehicle according to the exemplary embodiment of the present disclosure.

FIG. 4 is a diagram illustrating a control flow of the auxiliary battery system for the vehicle according to the exemplary embodiment of the present disclosure.

FIG. 5 is a flowchart for operating the auxiliary battery system for the vehicle according to the exemplary embodiment of the present disclosure.

### DETAILED DESCRIPTION OF THE DISCLOSURE

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

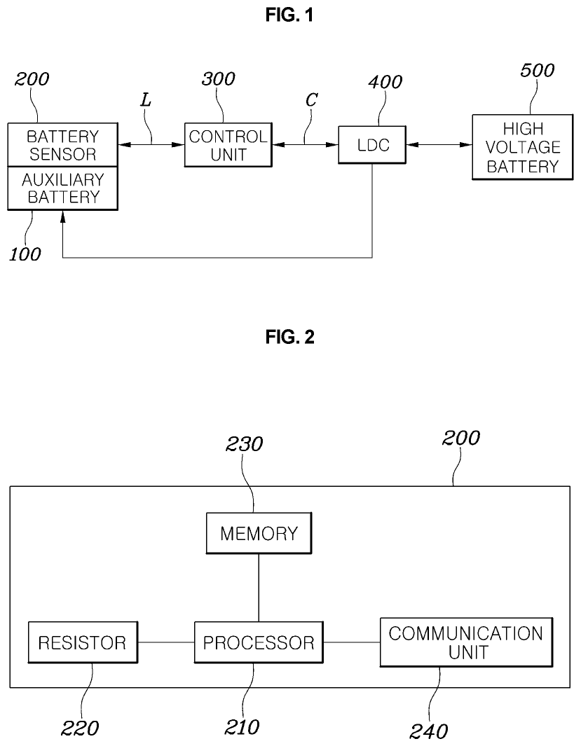

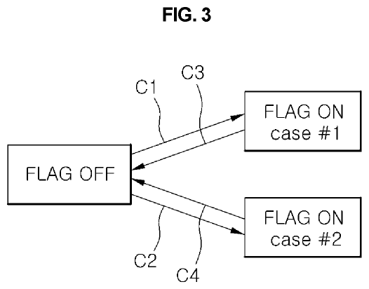

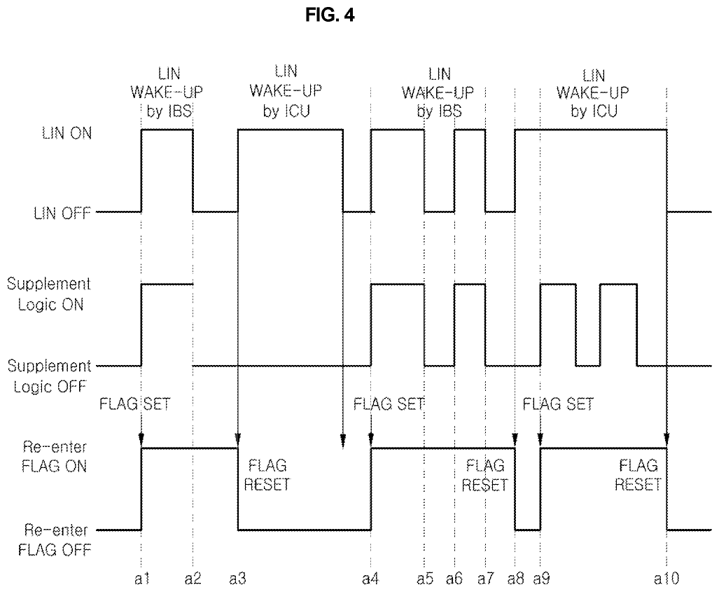

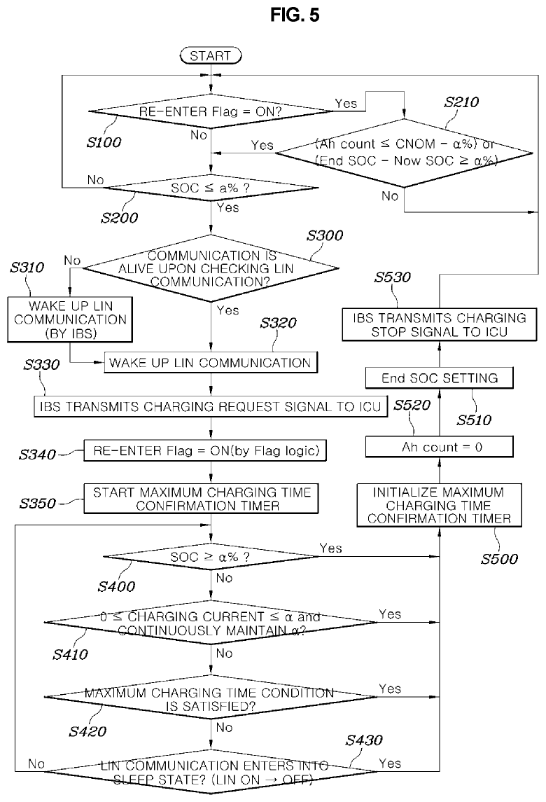

FIG. 1 is a diagram illustrating a configuration of an auxiliary battery system for a vehicle according to an exemplary embodiment of the present disclosure, FIG. 2 is a diagram illustrating a configuration of a battery sensor of the auxiliary battery system for the vehicle according to the exemplary embodiment of the present disclosure, FIG. 3 is a diagram illustrating a flag switching logic of the =Amy battery system for the vehicle according to the exemplary embodiment of the present disclosure, FIG. 4 is a diagram illustrating a control flow of the auxiliary battery system for the vehicle according to the exemplary embodiment of the present disclosure, and FIG. 5 is a flowchart for operating the auxiliary battery system for the vehicle according to the exemplary embodiment of the present disclosure.

FIG. 1 is a diagram illustrating a configuration of an auxiliary battery system for a vehicle according to an exemplary embodiment of the present disclosure, and an auxiliary battery system for a vehicle according to the present disclosure includes an auxillary battery 100 charged by a high voltage battery 500 for driving a vehicle, and configured to provide power to an electronic device of the vehicle; a battery sensor 200 configured to calculate the state of charge of the auxiliary battery 100; and a control unit 300 configured to communicate with the battery sensor 200, and to control the charging of the auxiliary battery 100 and the high voltage battery 500, in which a charging strategy of the auxiliary battery 100 may be different depending upon whether the communication between the battery sensor 200 and the control unit 300 is activated by a request of the battery sensor 200 or activated by a wake-up of the control unit 300.

The vehicle to which the present disclosure is applicable is a vehicle capable of driving by a driving motor through the high voltage battery 500, and using various electronic devices for the vehicle through the auxiliary battery 100, such as an electric vehicle, a fuel cell vehicle, or a hybrid vehicle. The electric vehicle or the like charges the auxiliary battery 100 through the power of the high voltage battery 500, and to this end, a converter (LDC) 400 configured to convert a voltage is provided in the middle thereof. Further, the control unit 300 charges the auxiliary battery 100 through such a control of the converter 400.

Meanwhile, if the auxiliary battery 100 is discharged during traveling or during parking, the vehicle may not start or it may be difficult to use major electronic components, such that the auxiliary battery 100 should always maintain the charging of a certain level or more.

The battery sensor 200 is provided to confirm whether the auxiliary battery 100 is abnormal and the state of charge thereof. The battery sensor 200 measures the state of charge (SOC) of the auxiliary battery 100. Further, as a result, the battery sensor 200 determines whether the auxiliary battery 100 is charged.

The present disclosure is characterized in that the battery sensor 200 does not simply measure a voltage, a current, or the state of charge of the auxiliary battery 100 but its own processor 210 and memory 230 illustrated in FIG. 2 are provided to actively determine the needs of the charging and to request it to the control unit 300.

Particularly, in the case of the parking of the vehicle or the like, for safety and to prevent the risk of the discharging, the high voltage battery 500 is blocked on the circuit and the control unit 300 also enters into a sleep state. In this case, there may occur a problem in that the auxiliary battery 100 is frequently discharged if the control unit 300 repeatedly wakes up by the sensing of the battery sensor 200.

For example, if the auxiliary battery 100 is discharged, the charging of the auxiliary battery 100 will be continuously requested, and the auxiliary battery 100 may continuously request the charging even when the state of charge of the high voltage battery 500 is insufficient or it is difficult to charge the high voltage battery 500 because a door, a hood, or the like is in an opened state. Further, in this case, the control unit 300 wakes up whenever the auxiliary battery 100 requests the charging but the auxiliary battery 100 may not be substantially charged, such that a vicious cycle may be repeated, and rather, the power of the auxiliary battery 100 is continuously consumed by the excessive wake-up of the control unit 300, and as a result, there may occur a problem in that the auxiliary battery 100 is fully discharged.

To prevent such a problem, the present disclosure is characterized in that a charging strategy of the auxiliary battery 100 is different depending upon whether the communication between the battery sensor 200 and the control unit 300 is activated by the request of the battery sensor 200 or activated by the wake-up of the control unit 300 itself not related to the charging issue of the control unit 300.

Specifically, FIG. 2 is a diagram illustrating a configuration of a battery sensor of the auxiliary battery system for the vehicle according to the exemplary embodiment of the present disclosure. As shown in FIG. 2, the battery sensor 200 according to the present disclosure is provided with the processor 210, the memory 230, a communication unit 240, and a resistor 220. The battery sensor 200 measures a state of the auxiliary battery 100, delivers the measured state to the processor 210, stores a flag in the memory 230, and communicates with the control unit 300 through the communication unit 240.

Particularly, the memory 230 stores the flag about whether the communication between the battery sensor 200 and the control unit 300 is activated by the request of the battery sensor 200 or activated by the wake-up of the control unit 300. The memory 230 may be provided outside the battery sensor 200 or in the control unit 300, but preferably, as in the exemplary embodiment, provided in the battery sensor 200 to allow the battery sensor 200 to selectively make the charging request itself.

FIG. 3 is a diagram illustrating a flag switching logic of the auxiliary battery system for the vehicle according to the exemplary embodiment of the present disclosure, and the state of the flag may be divided into an OFF state and an ON state, and switched into the ON state if the communication between the battery sensor 200 and the control unit 300 is activated by the charging request of the battery sensor 200.

FIG. 3 illustrates the switching logic of the flag stored in the memory 230, and the flag may be recorded as ON or OFF. Further, the switching logic may be summarized as follows.

C1: Case where LIN communication is activated by the charging request of the battery sensor

C2: Case where the LN communication is activated by the control unit and then there exists the charging request of the battery sensor

C3: Activation of the LIN communication by the control unit

C4: Inactivation of the LIN communication

Specifically, as illustrated in FIG. 1, the battery sensor 200 is connected to the control unit 300 through the LIN communication (L). Further, the control unit 300 serves as a master in the LIN communication (L) and the battery sensor 200 serves as a slave. Further, the control unit 300 is connected to other components via CAN communication (C).

Generally, the control unit 300 enters into a sleep mode if a separate control is not needed, thereby not communicating with other components and saving power. Further, in this case, the LIN communication (L) with the battery sensor 200 is also inactivated.

However, if the charging of the auxiliary battery 100 is needed, the battery sensor 200 senses it, and transmits a charging request signal to the control unit 300 via the LIN communication (L) according to the command of the processor 210, such that the control unit 300 wakes up and controls the LDC to charge the auxiliary battery 100.

To prevent an unnecessary and inefficient charging request in this process, the battery sensor 200 stores the flag in the memory 230.

Specifically, if the battery sensor 200 makes the charging request and thus the LIN communication is activated, the flag is recorded as the ON state. Further, the flag recorded as the ON state is later recorded as the flag OFF state only if the LIN communication is activated by the control unit 300, that is, for reasons not related to the issue of the auxiliary battery 100. In other cases, the flag is always maintained as the ON state.

Meanwhile, even when there exists the charging request of the battery sensor 200 in the state where the LIN communication wakes up by the control unit 300, the flag is recorded as the ON state. Further, in this case, only if the control unit 300 has no special role and thus is inactivated, the flag is recorded as the OFF state.

In other words, if the flag is switched into the ON state by the charging request of the battery sensor 200, the flag may be switched into the OFF state if the communication between the battery sensor 200 and the control unit 300 is activated by the wake-up of the control unit 300.

Further, a state of the flag may be divided into the OFF state and the ON state, and switched into the ON state if the communication between the battery sensor 200 and the control unit 300 is activated by the wake-up of the control unit 300 and then there exists the charging request of the battery sensor 200.

Further, in the case where the flag is switched into the ON state by the wake-up of the control unit 300 and the charging request of the battery sensor 200, the flag may be switched into the OFF state if the communication between the battery sensor 200 and the control unit 300 is inactivated by the control unit 300 entering the sleep mode.

Further, the state of the flag may be divided into the OFF state and the ON state, and switched into the ON state if the communication between the battery sensor 200 and the control unit 300 is activated by the charging request of the battery sensor 200 and if the communication between the battery sensor 200 and the control unit 300 is activated by the wake-up of the control unit 300 and then there exists the charging request of the battery sensor 200.

FIG. 5 is a flowchart for operating the auxiliary battery system for the vehicle according to the exemplary embodiment of the present disclosure, and first, the processor of the battery sensor confirms the flag of the memory before the auxiliary battery is charged (S100). If the flag is in the OFF state, the processor of the battery sensor confirms the activation of the LN communication if the state of charge of the auxiliary battery is a first standard level (e.g., 80%) or less and activates the LN communication through the battery sensor if the LN communication is in the inactivated state (S200, S300, S310). Further, the processor of the battery sensor transmits the charging request after the LN communication is activated, and records the flag as the ON state (S320, S330, and S340). Further, the charging is performed (S350).

This case corresponds to the charging of the auxiliary battery. However, a case where the flag is in the ON state as a result that the processor of the battery sensor confirms the flag of the memory may be a case where the auxiliary battery already requests the charging previously. Therefore, in this case, to prevent the frequent charging request, the charging request is made if a total amount of discharging of the auxiliary battery is larger than a second standard level of an initial chargeable amount or if a difference between previous and current SOCs is larger than the second standard level (S210). In the auxiliary battery, the initial chargeable amount capable of being maximally charged in the initial quality state is set therein, which is because the charging is necessarily needed if the auxiliary battery is discharged by a larger amount than 5% of the above value. Further, since the discharging is significantly performed even when a rate of a difference value between the previously recorded state of charge of the auxiliary battery and the current state of charge of the auxiliary battery exceeds 5%, the charging is needed.

In other words, it is possible to prevent the unnecessary charging request by not allowing the auxiliary battery to request the charging other than the case where the charging is necessarily needed as described above. Therefore, the auxiliary battery may make anew charging request only if the discharging is substantially significantly performed after the time point when already requesting the charging previously, and does not request the charging if no other new discharging is substantially performed.

For example, if the auxiliary battery is aged and may be charged up to only about 80% despite the maximum charging, the charging is allowed only if the auxiliary battery is substantially discharged after being charged once, and the auxiliary battery is not allowed to request the charging just because the absolute amount of the SOC is low.

As a result, it is possible to prevent the unnecessary and frequent charging request of the auxiliary battery, thereby solving the problem in that the auxiliary battery or the high voltage battery is continuously discharged and/or durability thereof is weakened because the control unit unnecessarily wakes up or is continuously awake.

Meanwhile, the auxiliary battery may be charged by the battery sensor making the charging request to the control unit. The charging of the auxiliary battery does not last indefinitely, but stops if a certain criterion is satisfied, thereby protecting the system and preventing unnecessary power consumption.

Specifically, the control unit may terminate the charging of the auxiliary battery if the state of charge (SOC) of the auxiliary battery reaches the first standard level upon charging the auxiliary battery (S400). In other words, the charging is stopped if a certain state of charge is obtained.

Further, the control unit may terminate the charging of the auxiliary battery even when a charging current is maintained to a fourth standard level or less upon charging the auxiliary battery (S410). This case is because it may be a case where the auxiliary battery is aged and not physically charged any more.

Further, the control unit may measure the charging time upon charging the auxiliary battery, and terminate the charging of the auxiliary battery if the charging time reaches the third standard level (S420). This case is also to prevent the excessive charging.

Further, the control unit may terminate the charging if the communication between the battery sensor and the control unit is inactivated by the control unit entering the sleep mode upon charging the auxiliary battery (S430). This case is a case where the capacity of the high voltage battery is insufficient or there is another problem in the vehicle, such that the control unit is inactivated, and this also terminates the charging to protect the system and prevent the full discharging.

If the charging is terminated, the measured charging time is initialized again and the discharging amount is also initialized, and the SOC of the auxiliary battery in this state is stored as a final SOC (S500, S510, and S520). Further, a charging termination signal is transmitted to the control unit (S530).

FIG. 4 is a diagram illustrating a control flow of the auxiliary battery system for the vehicle according to the exemplary embodiment of the present disclosure.

First, the LIN communication is activated upon charging request of the battery sensor and the flag is recorded as the ON state (a1). Further, if the charging is terminated, the LIN communication is also inactivated but the flag is still maintained as the ON state (a2). Thereafter, the LN communication is activated by the control unit for other reasons other than the charging and the flag is recorded as the OFF state (a3). Thereafter, the LIN communication is activated by the charging request by the battery sensor again, the charging is performed, and the flag is recorded as the ON state again (a4). In this case, if it is not a case where the LIN communication is activated by the control unit even if the charging is terminated, the flag is still in the ON state (a5). Therefore, the auxiliary battery may not frequently make the charging request just because the state of the charging is low, and the frequent charging request is restricted because the charging may be requested only if the discharging is substantially performed to some extent (a6, a7). Further, the flag is recorded as the OFF state only if the LN communication is activated by the control unit (a8). Further, if the charging request is made again in this state, the flag is recorded as the ON state (a9). This case is a case of C2 illustrated in FIG. 3 and a case where the flag is recorded as the OFF state again only if the LIN communication is inactivated, which is a case of C4 (a10).

The auxiliary battery system for the vehicle according to the present disclosure may prevent the phenomenon in which the power of the high voltage battery is unnecessarily consumed by the frequent charging request of the auxiliary battery, thereby solving the discharging problem of the high voltage battery during long-term parking and increasing the durability of the auxiliary battery and the high voltage battery.

While the specific exemplary embodiment of the present disclosure has been illustrated and described, it will be apparent to those skilled in the art that the present disclosure may be variously improved and changed without departing from the technical spirit of the present disclosure provided by the appended claims.

What is claimed is:

1. An auxiliary battery system for a vehicle, the auxiliary battery system comprising:
an auxiliary battery charged by a high voltage battery for driving the vehicle, and configured to provide power to an electronic device of the vehicle;
a battery sensor configured to calculate a state of charge of the auxiliary battery; and
a control unit configured to perform communication with the battery sensor, and to control charging of the auxiliary battery by the high voltage battery,
wherein a charging strategy of the auxiliary battery is different depending upon whether the communication between the battery sensor and the control unit is activated by a request of the battery sensor or activated by a wake-up of the control unit.

2. The auxiliary battery system for the vehicle according to claim 1, further comprising:
a memory configured to store a flag about whether the communication between the battery sensor and the control unit is activated by the request of the battery sensor or activated by the wake-up of the control unit.

3. The auxiliary battery system for the vehicle according to claim 2,
wherein the memory is provided in the battery sensor.

4. The auxiliary battery system for the vehicle according to claim 2,
wherein the flag is divided into an OFF state and an ON state, and switched into the ON state if the communication between the battery sensor and the control unit is activated by the charging request of the battery sensor.

5. The auxiliary battery system for the vehicle according to claim 4,
wherein in the case where the flag is switched into the ON state by the charging request of the battery sensor, the flag is switched into the OFF state if the communication between the battery sensor and the control unit is activated by the wake-up of the control unit.

6. The auxiliary battery system for the vehicle according to claim 2,
wherein the flag is divided into an OFF state and an ON state, and switched into the ON state if the communication between the battery sensor and the control unit is activated by the wake-up of the control unit and then there exists the charging request of the battery sensor.

7. The auxiliary battery system for the vehicle according to claim 6,
wherein in the case where the flag is switched into the ON state by the wake-up of the control unit and the charging request of the battery sensor, the flag is switched into the OFF state if the communication between the battery sensor and the control unit is inactivated by the control unit entering a sleep mode.

8. The auxiliary battery system for the vehicle according to claim 2,
wherein the flag is divided into an OFF state and an ON state, and switched into the ON state if the communication between the battery sensor and the control unit is activated by the charging request of the battery sensor and if the communication between the battery sensor and the control unit is activated by the wake-up of the control unit and then there exists the charging request of the battery sensor.

9. The auxiliary battery system for the vehicle according to claim 8,
wherein in the case where the flag is in the OFF state, the auxiliary battery is charged if the state of charge of the auxiliary battery is a first standard level or less.

10. The auxiliary battery system for the vehicle according to claim 8,
wherein in the case where the flag is in the ON state, the auxiliary battery is charged if a discharging amount or a discharging rate of the auxiliary battery is a second standard level or more.

11. The auxiliary battery system for the vehicle according to claim 10,
wherein the auxiliary battery is charged by the battery sensor making the charging request to the control unit.

12. The auxiliary battery system for the vehicle according to claim 1,
wherein the control unit terminates the charging of the auxiliary battery if the state of charge of the auxiliary battery reaches a first standard level upon charging the auxiliary battery.

13. The auxiliary battery system for the vehicle according to claim 1,
wherein the control unit terminates the charging of the auxiliary battery if a charging current is maintained to a fourth standard level or less upon charging the auxiliary battery.

14. The auxiliary battery system for the vehicle according to claim 1,
wherein the control unit measures a charging time upon charging the auxiliary battery, and terminates the charging of the auxiliary battery if the charging time reaches a third standard level.

15. The auxiliary battery system for the vehicle according to claim 1,
wherein the control unit terminates the charging if the communication between the battery sensor and the control unit is inactivated by the control unit entering a sleep mode upon charging the auxiliary battery.
